(19) United States
(12) Patent Application Publication
(10) Pub. No.: US 2006/0131066 A1
(43) Pub. Date: Jun. 22, 2006

(54) Adhesive closing device provided with a switching circuit

(76) Inventor: Jan Tuma, Herrenberg (DE)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/541,827

(22) PCT Filed: Oct. 11, 2003
(86) PCT No.: PCT/EP03/11283

§ 371 Date: Jul. 11, 2005

(30) Foreign Application Priority Data
Jan. 13, 2003 (DE) 10301424.1

(51) Int. Cl. H05K 1/03

(52) U.S. Cl. 174/259; 174/260

(57) ABSTRACT

The invention relates to a closing device (1, 101, 201, 301) consisting of a plurality of adhesive closing elements (2) in the form of a book, mushroom head or clasp. The inventive closing device (1, 101, 201, 301) comprises a flat support (3, 103, 203, 303) and the adhesive closing elements (2) protruded from at least one surface (4) of the support (3, 103, 203, 303). Said invention is characterized in that said adhesive closing device (1, 101, 201, 301) is provided with at least one switching circuit (5, 503) comprising at least one electric and/or electronic component (6, 106; 7, 107, 207, 307).

The invention relates to an adhesive closure part according to the preamble of claim 1.

These adhesive closure parts are known for example from DE 196 46 318 A1. An adhesive closure which is generally formed from two adhesive closure parts which can be dynamically connected to one another is often used in textile or other articles of clothing and is also know as a velcro closure. Further applications are for example installation technology, for example for attaching elements of the inside lining in automotive engineering, or in general the production of a detachable mounting.

The object of the invention is to increase the functionality of adhesive closure parts and adhesive closures.

This object is achieved by the adhesive closure part defined in claim 1. Special embodiments of the invention are determined in the dependent claims.

In an adhesive closure part with a plurality of adhesive closure elements such as for example hooks, mushrooms or loops, the adhesive closure part having a flat carrier and the adhesive closure elements projecting from at least one surface of the carrier, the object is achieved in that the adhesive closure part has a circuit which has at least one electrical and/or electronic component.

Preferably the carrier and/or the adhesive closure elements are made of plastic. For example the plastic can be thermoplastically shaped and a process as claimed in DE 196 46 318 A1 is used to produce the adhesive closure elements. Alternatively to a thermoplastic, a duroplastic, polymer plastic, acrylate plastic or other suitable plastic can be used. Preferably the adhesive closure elements are configured integrally with the carrier. Alternatively the adhesive closure elements can also be produced as described in DE 101 06 705 C1, in particular with an application device by which the adhesive closure elements are built up in successively delivered droplets.

In one special version of the invention the electrical and/or electronic component is located on and/or in the flat carrier. To the extent the component is located on the surface of the carrier, this can take place in an area which is free of adhesive closure elements. In particular the adhesive closure elements can be located on only one side of the carrier and the component can be located on the opposing side of the carrier. Depending on the respective application case, the component can also be located between or on the adhesive closure elements.

To the extent the component is integrated into the flat carrier, this can take place in a hybrid or even monolithic manner, in particular the carrier or its material itself can have an electrical and/or electronic functionality. Thus, for example, when a corresponding plastic is used for the carrier there can optionally be locally limited electrical conductivity for making available strip conductors. Alternatively or in addition, the carrier can also have semiconductor properties, at least locally limited, so that circuitry intelligence can be integrated into the compartmented carrier.

In one preferred embodiment the component is applied to the flat carrier in thick or thin film technology. Thus for example electrical conductor strips can also be provided on the carrier by structured or unstructured coating, for example printing, precipitation or vapor deposition. Packaging technology discloses partially aluminized packaging foils, the aluminum coating for the packaging foils being intended for a completely different purpose, specifically as diffusion barriers. When using the corresponding printing or coating technologies, aluminum strips which are structured at least in areas, or conductor strips consisting of some other electrically conductive material, can be made available comparatively easily on the carrier.

In this way electrical sensors can also be made available which signal for example the application of a force to the adhesive closure part. In this way an adhesive closure part which is used for example to attach a coating material for a motor vehicle seat can at the same time electrically signal whether an individual has sat down on the seat or not and accordingly the safety devices such as the belt tensioner or airbags of the vehicle can be controlled.

Above and beyond these simple electrical sensors which are formed essentially by conductor strips, it is possible to implement sensors, actuators and data processing technology of almost any complexity on the carrier. To do this for example electronic sensors and/or integrated semiconductor components can be provided on or in the carrier. At least some of the electrical and/or electronic components can also be applied to another carrier which is laminated onto the flat carrier of the adhesive closure element or is joined to the flat carrier.

For example, so-called smart labels can be implemented by the adhesive closure part as claimed in the invention; they can be easily attached and removed again as many times as wished on articles of clothing, items or the like as intelligent labels due to the mechanical functionality of the adhesive closure part.

In one special embodiment the integrated semiconductor component has an electronic data memory. It can be a read-only memory (ROM) or also a programmable read-only memory (PROM). In particular, erasable programmable read-only memories (EPROM) or even electronically erasable programmable read-only memories (EEPROM) are advantageous. For example, identification or authorization data can be stored in the data memory. Thus, for example access authorization to security-relevant spaces, vehicles, functions or the like can be filed in such a data memory.

Alternatively or in addition, biometric features of living creatures, especially of individuals, can be stored which are used for recording and storing characteristic and individual features. Such an adhesive closure part can easily be for example detachably mounted on an article of clothing of a correspondingly authorized individual who has the corresponding access authorizations using this adhesive closure part.

In this connection it is especially advantageous if the data which are stored in the data memory can be read out without contact. Preferably the adhesive closure part forms a type of transponder which in any case transmits some of the stored data upon a corresponding electronic interrogation. The pertinent reading station can be stationary or portable.

The energy which is required for information transmission between the adhesive closure part and the reading station can be coupled into the circuit in the adhesive closure part without contact by an electromagnetic field. The circuit for this purpose has at least one receiving coil which can also be formed for example by a correspondingly structured conductor strip.

Alternatively or in addition, the circuit can have an energy storage device, especially an electrochemical energy storage device in the form of a battery or a rechargeable battery. Alternatively or in addition, capacitive or other energy storage devices can also be used. Preferably the energy storage device is also made using thin or thick film technology so that the adhesive closure part overall has a small thickness.

Preferably data can also be stored in the data memory without contact so that not only can information be read out of the memory, but also new and optionally updated information can be written into the memory. These writing processes preferably also take place without contact and like the reading process do not require direct visual contact between the adhesive closure part and the reading device. The attainable communications ranges in the corresponding systems which are known from other applications are up to one meter or more. The range is determined essentially by the power of the transmitter and/or by the size of the antenna of the read/write device. When an energy storage device which is integrated into the adhesive closure part is used, fundamentally longer ranges can be achieved.

The applications of these intelligent adhesive closure parts are very widely diversified, in particular they can be used for applications for which adhesive closure parts have not been used in the past. The mechanical functionality of the adhesive closure part allows simple and repeatable attachment and removal of electronic intelligence on individuals or articles of clothing or on items. Since transmission of the information does not require visual contact, the adhesive closure parts can also be located hidden, for example on the inside of an article of clothing or on the side of an item which is not visible.

Other advantages, features and details of the invention arise from the dependent claims and the following description in which several embodiments are detailed with reference to the drawings. Here the features mentioned in the claims and in the description are individually critical to the invention for themselves or in any combination.

FIG. 1 shows a cross section through an adhesive closure with an adhesive closure part as claimed in the invention,

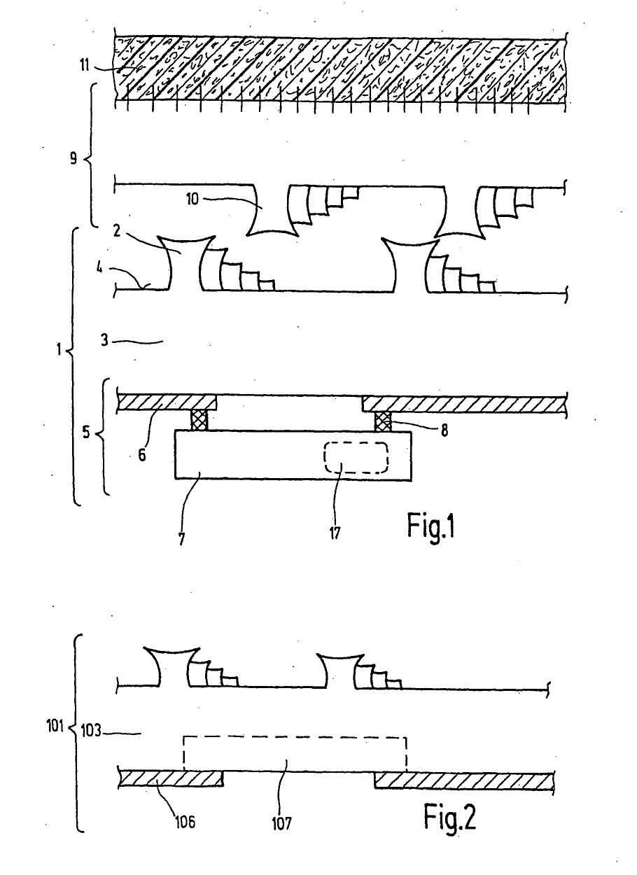

FIG. 2 shows a second embodiment of the invention,

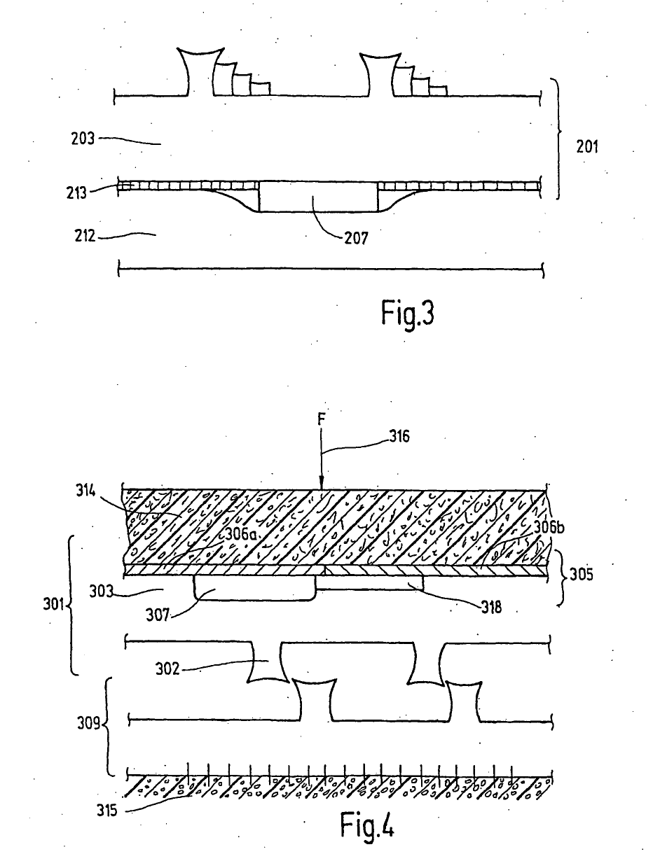

FIG. 3 shows a third embodiment of the invention, and

FIG. 4 shows a fourth embodiment of the invention.

FIG. 1 shows a cross section through an adhesive closure with an adhesive closure part 1 as claimed in the invention. The latter has a plurality of adhesive closure elements 2 which are regularly located in rows and columns and which are formed integrally with the flat carrier 3 from a formable thermoplastic and project from one surface 4 of the carrier 3 obliquely and preferably at a right angle. On the surface opposite the adhesive closure elements 2, the adhesive closure part 1 has a circuit 5 which in this embodiment has both an electrical component in the form of a conductor strip 6 and also an electronic component in the form of an integrated semiconductor component 7.

The printed conductors 6 are formed by a structured aluminum coating on the side of the carrier 3 which faces away from the adhesive closure elements 2. The connection to the terminalelectrodes of the semiconductor component 7 takes place by way of so-called bumps 8. The function and complexity of the semiconductor component 7 are matched to the respective application. In this way the semiconductor component 7 can consist for example essentially of a temperature sensor, optionally with a storage means for regular or event-dictated storage of determined temperature values, for example when a given temperature value is exceeded or not reached. To do this, the semiconductor component 7 in one partial area has a data memory 17 from which data can be read out preferably without contact and data can be stored likewise preferably without contact. These data can be routed by way of the conductor strips 6 to outside the adhesive closure part 1. In another application, the semiconductor component 7 can contain for example a complete transponder which communicates identification data without contact with a corresponding read/write device.

The adhesive closure part 1 which is equipped as claimed in the invention, by means of the adhesive closure elements 2, can be connected in a mechanically secure but detachable manner to another adhesive closure part 9 which is configured essentially identically with respect to its mechanical functionally by engagement of the adhesive closure elements 2, 10 which correspond to one another. The other adhesive closure part 9 can be sewed, cemented or in some other way applied securely and generally undetachably to a textile or other article of clothing. Therefore the adhesive closure part 1 which is equipped as claimed in the invention can be detachably fixed on an article of clothing 11. The adhesive closure part 1 which is equipped as claimed in the invention thus combines the mechanical attachment possibilities of conventional adhesive closures with the more or less complex control function of electrical and/or electronic components and can thus be called a smart fastener or an intelligent adhesive closure.

FIG. 2 shows a second embodiment of the invention. The adhesive closure part 101 likewise has a thermoplastically formable carrier 103 into which the semiconductor component 107 is integrated. This integration can be done in hybrid form, for example by inserting a semiconductor component 107 into a correspondingly provided or impressed recess in the carrier 103. Depending on the capabilities and properties of the carrier 103 and of the pertinent material, the control intelligence can also be monolithically implemented in the material of the carrier 103, for example by influencing, in a concerted manner, the semiconductor areas which are optionally locally bounded in the carrier 103. Contact-making of the electronic component 107 which is integrated in a monolithic or hybrid manner takes place in turn by conductor strips 106 which in this case are produced by structured coating of the corresponding surface of the carrier 103.

FIG. 3 shows a third embodiment of the invention. Here the electronic component 207 is applied to another carrier 212 which is laminated onto the flat carrier 203 of the adhesive closure element 201 by means of a cement layer 213.

FIG. 4 shows a fourth embodiment of the invention. The adhesive closure part 301 as claimed in the invention which is located in the center of the drawing, on its side which faces away from the adhesive closure elements 302 and on which the circuit 305 is located, is securely and undetachably fixed on a textile covering 314 which can be used for example for covering the upholstery of a vehicle seat. On the surface which faces away from the adhesive closure elements 302 the adhesive closure part 301 has conductor strips 306a, 306b which abut one another. The adhesive closure part 301 can be detachably fixed on an upholstery part 315 which has another corresponding adhesive closure part 309 for this purpose by means of the adhesive closure elements 302 and together with the textile covering 314.

In the case of the action of a force F in the direction of the arrow 316, for example by an individual sitting down on the vehicle seat, more or less major deflection of the upholstery part 315 and thus also of the adhesive closure part 301 takes place and especially the distance and interface between the conductor strips 306a, 306b changes. This is accompanied by a change of the electrical contact resistance which can be communicated directly or indirectly to outside the adhesive closure part 301 by way of the electronic component 307 which is integrated into the carrier 303. The electronic component 307 is provided only as an option for contactless communications and/or as an option for implementation of other control intelligence or other sensors. In particular, sensor functions can also be provided even without the electronic semiconductor component 307 in the adhesive closure part 301, for example also pressure or moisture sensors, by the corresponding comb-like arrangements of conductor paths.

Immediately next to the semiconductor component 307 or optionally also spaced apart from it, but electrically connected to it, the adhesive closure part 301 has an energy storage device 318 in thin or thick film technology, preferably an electrochemical energy storage device 318 in the form of a battery or a rechargeable battery.

The conductor strips can be implemented by structured or unstructured application of metal layers, in the case of unstructured application such as for example vapor deposition or precipitation from the gaseous phase, subsequent structuring can take place mechanically, chemically or in some other way. All the materials which are used for the adhesive closure part 1, 101, 201, 301 as claimed in the invention, especially the plastics used, are preferably recyclable and/or biologically decomposable.

1. Adhesive closure part (1, 101, 201, 301) with a plurality of adhesive closure elements (2) such as for example hooks, mushrooms or loops, the adhesive closure part (1, 101, 201, 301) having a flat carrier (3, 103, 203, 303) and the adhesive closure elements (2) projecting from at least one surface (4) of the carrier (3, 103, 203, 303), and the adhesive closure elements (2) consisting of an electrically insulating plastic, characterized in that the adhesive closure part (1, 101, 201, 301) has a circuit (5, 305) which has at least one electrical and/or electronic component (6, 106; 7, 107, 207, 307), and that the circuit (5, 305) is located on the side of the carrier (3, 103, 203, 303) opposite the electrically insulating adhesive closure elements (2).

2. Adhesive closure part (1, 101, 201, 301) as claimed in claim 1, wherein a further electrical and/or electronic component (6, 106; 7, 107, 207, 307) is located on and/or in the flat carrier (3, 103, 203, 303).

3. Adhesive closure part (1, 101, 201, 301) as claimed in claim 1, wherein a further electrical and/or electronic component (6, 106; 7, 107, 207, 307) is integrated into the flat carrier (3, 103, 203, 303).

4. Adhesive closure part (1, 101, 201, 301) as claimed in one of claim 1, wherein the electrical and/or electronic component (6, 106; 7, 107, 207, 307) is applied in thick or thin film technology to the flat carrier (3, 103, 203, 303).

5. Adhesive closure part (201) as claimed in claim 1, wherein a further electrical and/or electronic component (6, 106; 7, 107, 207, 307) is applied to another carrier (212) which is laminated onto the flat carrier (3, 103, 203, 303) of the adhesive closure part (1, 101, 201, 301).

6. Adhesive closure part (1, 101, 201, 301) as claimed in one of claim 1, wherein the circuit (5, 305) has electrical conductor strips (6, 106).

7. Adhesive closure part (1, 101, 201, 301) as claimed in claim 1, wherein the circuit (5, 305) has electrical and/or electronic sensors (306a, 306b).

8. Adhesive closure part (1, 101, 201, 301) as claimed in one of claim 1, wherein the circuit (5, 305) has an integrated semiconductor component (7, 107, 207, 307).

9. Adhesive closure part (1, 101, 201, 301) as claimed in claim 8, wherein the integrated semiconductor component (7, 107, 207, 307) has an electronic data memory (17).

10. Adhesive closure part (1, 101, 201, 301) as claimed in claim 9, wherein the data stored in the data memory (17) can be read out without contact.

11. Adhesive closure part (1, 101, 201, 301) as claimed in claim 9, wherein data can be stored in the data memory (17) without contact.

12. Adhesive closure part (1, 101, 201, 301) as claimed in claim 1, wherein the electrical energy for operating the circuit (5, 305) can be coupled without contact into the circuit (5, 305) which has at least one receiving coil for this purpose by an electromagnetic field.

13. Adhesive closure part (1, 101, 201, 301) as claimed in claim 1, wherein the circuit (5, 305) has an energy storage device (318), especially an electrochemical energy storage device (318) in thin or thick film technology.

14. Adhesive closure part (1, 101, 201, 301) as claimed in claim 1, wherein the carrier (3, 103, 203, 303) and/or the adhesive closure elements (2) are produced from a duroplastic, thermoplastic, polymer plastic or an acrylate plastic.
